(19) United States
(12) Patent Application Publication
(10) Pub. No.: US 2025/0311346 A1
(43) Pub. Date: Oct. 2, 2025

(54) EPITAXIAL WAFER FOR GAN HEMT WITH ENHANCED ELECTRICAL INSULATION AND MANUFACTURING METHOD THEREOF

(71) Applicant: WAVELORD CO., LTD, Gyeonggi-do (KR)

(72) Inventors: June O. SONG, Gyeonggi-do (KR); Young Hun Han, Gyeonggi-do (KR); Hyun Chul Lim, Gyeonggi-do (KR)

(21) Appl. No.: 19/098,220

(22) Filed: Apr. 2, 2025

(30) Foreign Application Priority Data
Apr. 2, 2024 (KR) 10-2024-0044864
Jul. 15, 2024 (KR) 10-2024-0093015

(51) Int. Cl. H10D 62/85; C30B 25/18; C30B 29/40; H01L 21/02; H10D 30/47

(52) U.S. Cl. CPC H10D 62/8503; C30B 25/183; C30B 29/403; C30B 29/406; H01L 21/02378; H01L 21/02458; H01L 21/0254; H10D 30/471

(57) ABSTRACT

Embodiments according to the present disclosure provide an epitaxy wafer for a GaN HEMT with enhanced electrical insulation, comprising: a growth substrate; a nucleation region grown on the growth substrate; a high-resistance region having electrically high resistance characteristics, which comprises a high-resistance unit region defined by a first region grown as a group III nitride semiconductor doped with carbon and a second region grown as a group III nitride semiconductor on the first region, which is provided on the nucleation region; and an active region including a channel region grown on the high-resistance region and a barrier region grown on the channel region.

### CROSS-REFERENCE TO RELATED APPLICATIONS

This application claims priority to Korean Patent Application Nos. 10-2024-0044864, filed on Apr. 2, 2024 and 10-2024-0093015 filed on Jul. 15, 2024. The entire disclosure of the applications identified in this paragraph is incorporated herein by reference.

### FIELD

The present disclosure relates to an epitaxial wafer for a GaN HEMT with enhanced electrical insulation and a manufacturing method thereof, and more specifically, to an epitaxial wafer for a GaN HEMT with enhanced electrical insulation and a manufacturing method thereof, which can electrically insulate the channel region and the growth substrate while using an electrically semi-insulating substrate and an inexpensive conductive substrate as the growth substrate, and can significantly improve the film quality of the channel region.

### BACKGROUND

Epitaxial wafer for GaN HEMT power semiconductor with horizontal channel structure generally requires a semi-insulating growth substrate, and materials such as silicon carbide (SiC) and silicon (Si) are used.

Semi-insulating SiC substrate and Si material growth substrate have surface damage (Surface Damage) during the growth of the epitaxial layer, which generates a leakage current path in the vertical direction, resulting in a deterioration in performance and quality.

To solve this problem, a high-resistance region grown with C- or Fe-doped GaN is introduced before growing the active region (channel region, barrier region).

However, this results in a deterioration in the crystal quality of the active region.

Therefore, it is crucial to develop a technology that can use a semi-insulating substrate or an electrically conductive substrate as a growth substrate while minimizing the occurrence of crystal defects on the surface where the active region is grown, improving the film quality of the active region, and minimizing the possibility of a leakage current path in the vertical direction.

### SUMMARY

### Technical Problem

The present invention aims at providing an epitaxy wafer for GaN HEMT with enhanced electrical insulation and a method for manufacturing the same, which can use not only a semi-insulating substrate but also a inexpensive conductive substrate as a growth substrate, and which can improve both high-resistance characteristics and the film formation quality of an active region.

### Technical Solution

Embodiments according to the present invention provide an epitaxy wafer for a GaN HEMT with enhanced electrical insulation, comprising: a growth substrate; a nucleation region grown on the growth substrate; a high-resistance region having electrically high resistance characteristics, which comprises a high-resistance unit region defined by a first region grown as a group III nitride semiconductor doped with carbon and a second region grown as a group III nitride semiconductor on the first region, which is provided on the nucleation region; and an active region including a channel region grown on the high-resistance region and a barrier region grown on the channel region.

In embodiments according to the present invention, the high resistance region is provided by stacking the high resistance unit regions two or more times.

In embodiments according to the present invention, the first region is provided with a carbon doping concentration of 5×10¹⁷/cm³ or more, preferably 1×10¹⁸/cm³ or more.

In embodiments according to the present invention, the first region is formed of one of aluminum nitride (AlN), aluminum gallium nitride (AlGaN), or gallium nitride (GaN), and the second region is formed of aluminum nitride (AlN).

In embodiments according to the present invention, a high-resistance GaN region made of aluminum gallium nitride (AlGaN) or gallium nitride (GaN) may be further included between the high-resistance region and the active region.

Embodiments of a manufacturing method according to the present invention provide a method for manufacturing an epitaxial wafer for a GaN HEMT with enhanced electrical insulation, comprising: preparing a growth substrate; forming a nucleation region by epitaxially growing a nucleation region on the growth substrate; forming a first region by epitaxially growing a carbon-doped group III nitride semiconductor layer on the nucleation region; forming a second region by epitaxially growing a group III nitride semiconductor layer at a temperature relatively higher than that of the first region forming step on the first region; repeating the steps of forming the first and second regions; and forming an active region by forming a channel region on the second region, the channel region having an energy bandgap smaller than that of the second region, and a barrier region grown on the channel region.

In embodiments of the manufacturing method according to the present invention, the growth substrate is formed of silicon carbide (SiC) and silicon (Si) materials, the nucleation region is formed of aluminum nitride (AlN), the first region is formed of one of aluminum nitride (AlN), aluminum gallium nitride (AlGaN), and gallium nitride (GaN), and the second region is formed of aluminum nitride (AlN).

In embodiments of the manufacturing method according to the present invention, the first region forming step is performed at a temperature of 900 to 1100° C., and the second region forming step is performed at a temperature of 1150 to 1300° C.

In embodiments of the manufacturing method according to the present invention, the method further includes a step of forming a high-resistance GaN region made of aluminum gallium nitride (AlGaN) or gallium nitride (GaN) between the high-resistance region and the active region.

In embodiments of the manufacturing method according to the present invention, the first region forming step is performed at a V/III Ratio of 250 to 400 and a pressure of 50 to 70 mbar.

### Advantageous Effects

According to the present invention, by employing a high-resistance region structure in which a high-concentration carbon-doped group III nitride semiconductor layer epitaxially grown at low temperature and a group III nitride semiconductor layer grown at high temperature are repeatedly laminated, even when an electrically semi- insulating substrate and an electrically conductive substrate are used as a growth substrate, electrical insulation can be achieved between a channel region and a growth substrate, and the film formation quality of the channel region can be dramatically improved.

### BRIEF DESCRIPTION OF DRAWINGS

FIG. 1 is a drawing showing an epitaxial wafer for GaN HEMT with enhanced electrical insulation according to an embodiment of the present invention.

FIG. 2 is a drawing showing an epitaxial wafer for GaN HEMT with enhanced electrical insulation according to another embodiment of the present invention.

FIGS. 3, 4, 5, 6, 7 and 8 are drawings explaining a method for manufacturing an epitaxy wafer for GaN HEMT with enhanced electrical insulation according to an embodiment of the present invention.

### DETAILED DESCRIPTION

Hereafter, embodiments of an epitaxy wafer for GaN HEMT with enhanced electrical insulation according to the present invention and a manufacturing method thereof will be described in detail with reference to the drawings.

The terms to be used hereafter are selected for the convenience of description and should be appropriately construed as meanings coinciding with the intrinsic spirit of the present disclosure, not being limited to the meanings in dictionaries when finding out the spirit of the present disclosure.

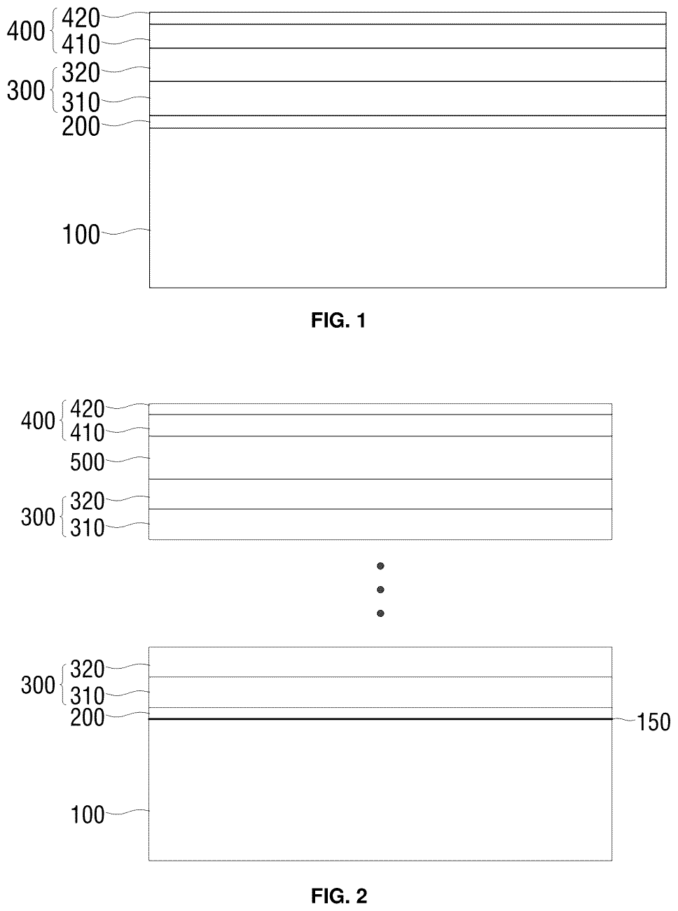

Referring to FIG. 1, an epitaxy wafer for a GaN HEMT with enhanced electrical insulation according to an embodiment of the present invention includes a growth substrate (100), a nucleation region (200), a high-resistance region (300), and an active region (400).

The growth substrate (100) may be an electrically conductive or semi- insulating substrate.

The nucleation region (200) is epitaxially grown on the growth substrate (100).

The high-resistance region (300) has a first region (310) on the lower side and a second region (320) on the upper side.

The first region (310) is formed as a group III nitride semiconductor layer doped with carbon on the nucleation region (200).

The second region (320) is formed as a group III nitride semiconductor layer on the first region (310).

The second region (320) has the function of restoring the crystallinity damaged by carbon (C) doping during the growth process of the first region (310).

For this purpose, it is desirable to make the growth temperature of the second region (320) higher than the growth temperature of the first region (310).

The active region (400) includes a channel region (410) formed on the second region (320) and a barrier region (420) formed on the channel region (410).

The channel region (410) has a 2DEG (2-Dimensional Electron Gas) formed by a gate voltage applied by a gate electrode formed on the upper side of the barrier region (420).

The active region (400) may further include a group III nitride p-type semiconductor layer, a passivation layer, or a capping layer formed on the barrier region (420).

The energy bandgap of the second region (320) is provided to be larger than the energy bandgap of the channel region (410).

The channel region (410) is electrically insulated due to the second region (320) having a larger energy band gap than the channel region (410).

The growth substrate (100) is preferably made of silicon carbide (SiC) or silicon (Si), which is a semi-insulating or electrically conductive material. Since it is relatively inexpensive, it can secure high cost-effectiveness of GaN HEMT.

The nucleation region (200) may be formed of aluminum nitride (AlN).

The first region (310) is preferably formed of one of aluminum nitride (AlN), aluminum gallium nitride (AlGaN), and gallium nitride (GaN), and the second region (320) is preferably formed of aluminum nitride (AlN).

The second region (320) minimizes the adverse effects on the film quality of the channel region (410), thereby implementing a high-quality of the channel region (410).

Since the second region (320) has an energy band gap larger than the energy band gap of the channel region (410), the channel region (410) and the second region (320) are a heterojunction structure.

Accordingly, an energy barrier is formed in each of the conduction band and the valence band from the channel region (410) toward the second region (320).

This energy barrier prevents electrons in the conduction band and holes in the valence band from leaking to the lower outside of the channel region (410), i.e., the second region (320).

Therefore, the second region (320) has high resistance characteristics, i.e., electrical insulation characteristics.

The resistance characteristics of the second region (320) formed due to the difference in energy band gaps are more stable than the high resistance characteristics formed by injecting impurities, etc.

The high-resistivity region grown with C- or Fe-doped GaN used in conventional GaN HEMT structures acquires its resistivity by injecting carbon or iron as traps inside.

However, since carbon or iron have energy levels that change depending on temperature, there is a problem in securing resistance over a wide temperature range (especially at high temperatures).

In contrast, as in the present embodiment, the high resistance due to the energy barrier formed due to the difference in band gap between different materials is insensitive to temperature changes, so the phenomenon of increased leakage current is minimized even in a wide temperature range, and thus has the advantage of being usable in a wide temperature range.

The first region (310) is electrically resistive due to carbon doping.

The carbon doping concentration of the first region (310) is 5×10¹⁷/cm³ or more, preferably 1×10¹⁸/cm³ or more.

The first region (310) formed using AlN or GaN doped with high concentration of carbon forms a high resistance region together with the undoped second region (320) and provides enhanced high resistance characteristics.

Next, referring to FIG. 2, the first region (310) and the second region (320) are sequentially and repeatedly grown two or more times to form a high-resistance region (300).

At this time, the laminated first region (310) and the second region (320) are defined as a high-resistance unit region. That is, the present embodiment is provided with the high-resistance unit region laminated two or more times.

Accordingly, the electrical insulation is strengthened, and there is an advantage in that the tensile stress applied to the active region (400), particularly the channel region (410), is minimized.

In addition, when the first region (310) and the second region (320) are repeatedly laminated, the stress applied from the growth substrate is reduced in the first region (310) and the second region (320) laminated on the upper side.

Therefore, the second region (320) that is repeatedly laminated has the effect of further improving the film formation quality of the uppermost second region (320) in proportion to the number of times it is laminated.

Meanwhile, the embodiments of FIGS. 1 and 2 may further include a carbon layer formed as a Si-C bond layer between the growth substrate (100) and the nucleation region (150).

It is preferable that the carbon layer (150) be formed with a thickness of 0.1 to 10 nm in an amorphous, polycrystalline, or single-crystalline form.

The embodiments of FIGS. 1 and 2 form a further enhanced high-resistance region by sequentially growing the first region (310) and the second region (320) so as to overlap the unique high-resistance characteristics of each region.

The first region (310) implements high resistance characteristics by carbon doping, and the second region (320) implements high resistance characteristics by utilizing an energy barrier due to a band gap difference.

The second region (320) must be epitaxially grown to have excellent film quality and low defect density.

To this end, the second region (320) is grown at a higher temperature than the growth temperature of the first region (310).

The second region (320) with excellent film quality and low defect density maintains excellent film quality of the channel region (410).

The nucleation region (200) has a thickness of less than 100 nm, and is typically grown on the growth substrate (100) with a thickness of several tens nm.

If the second region (320) is grown directly on the nucleation region (200), problems such as breakage and delamination are expected due to stress generated due to the difference in lattice constant with the growth substrate (100).

Stress generation creates various leakage paths, which is the main cause of the high resistance characteristics of the second region (320), i.e., the insulation function, being lost.

For this reason, in order to achieve stable growth of the second region (320) grown at high temperature, the first region (310) must first be formed between the nucleation region (200) and the second region (320).

The first region (310) serves as a stress buffer that can minimize stress generated when the second region (320) is grown at high temperature.

Meanwhile, in order to minimize stress generated due to differences in lattice constants and thermal expansion coefficients between the first region (310) and the second region (320), it is preferable that the first region (310) be made of the same material as the second region (320).

Meanwhile, it is desirable to minimize stress generation between the first region (310) and the growth substrate (100).

To this end, the first region (310) is grown at a relatively low temperature.

In addition, the first region (310) should be carbon-doped to prevent crystal defects and deterioration of resistance characteristics due to low-temperature growth, and high-concentration doping of at least 5×10¹⁷/cm³ is desirable.

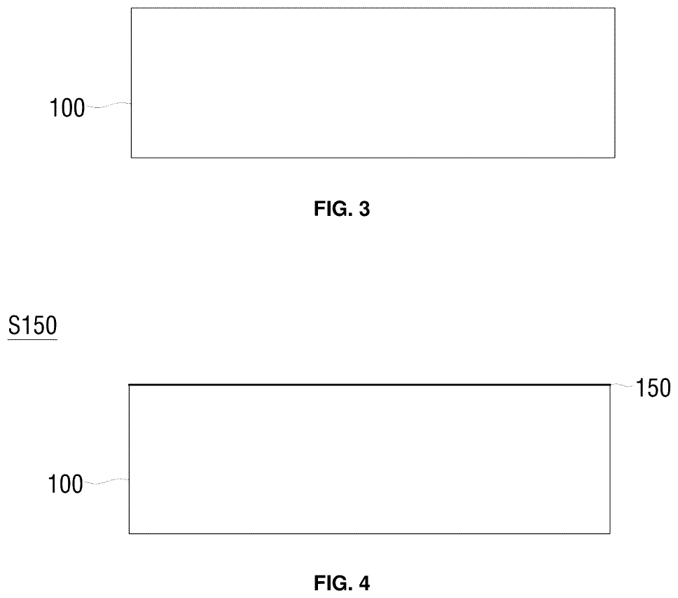

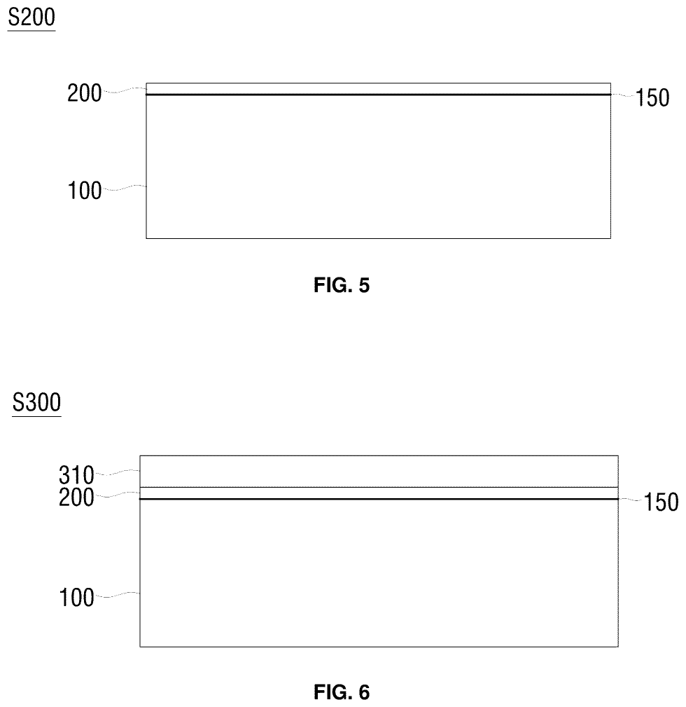

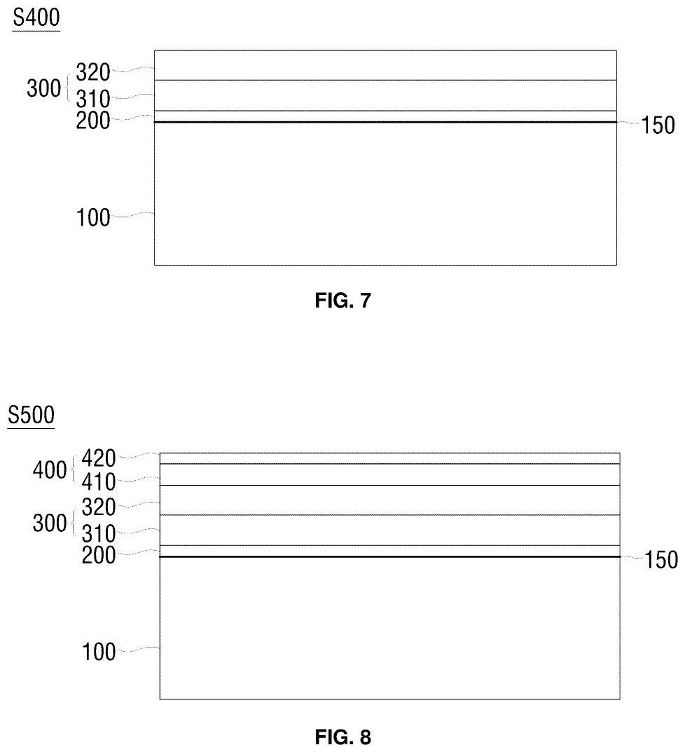

Next, an embodiment of a manufacturing method according to the present invention will be described with reference to FIGS. 3 to 8.

This is characterized by a method of forming the first region (310) and the second region (320).

Referring to FIGS. 3 to 8, a method for manufacturing an epitaxy wafer for GaN HEMT with enhanced electrical insulation according to the present embodiment includes a growth substrate preparation step (S100), a nucleation region formation step (S200), a first region formation step (S300), a second region formation step (S400), and an active region formation step (S500).

Prior to forming the active region, it is preferable to include a step of repeating the steps (S300, S400) of forming the first and second regions.

The growth substrate preparation step (S100) prepares an electrically conductive or semi-insulating growth substrate (100).

The growth substrate (100) is preferably selected from silicon carbide (SiC) and silicon (Si) wafer materials.

The nucleation region formation step (S200) epitaxially grows a nucleation region (200) on the growth substrate (100).

The nucleation region (200) is preferably made of aluminum nitride (AlN) material.

The first region formation step (S300) grows a first region (310) on the nucleation region (200) as a carbon-doped group III nitride semiconductor layer.

The second region forming step (S400) forms the second region (320) as a group III nitride semiconductor layer on the first region (310) at a relatively higher temperature than the first region forming step (S300).

In the active region forming step (S500), the channel region (410) and the barrier region (420) are formed sequentially.

The energy bandgap of the material forming the second region (320) is higher than the energy bandgap of the material forming the channel region (410).

The first region (310) is preferably made of aluminum nitride (AlN), aluminum gallium nitride (AlGaN), and gallium nitride (GaN), and the second region (320) is preferably made of aluminum nitride (AlN).

The first region forming step (S300) is performed at a temperature of 900 to 1100° C., and the second region forming step (S400) is performed at a temperature of 1150 to 1300° C.

The first region forming step (S300) is performed so that the carbon doping concentration of the first region (310) is 5×10¹⁷/cm³ or more. Preferably, it is 1×10¹⁸/cm³ or more.

At this time, the first region forming step (S300) is preferably performed at a V/III Ratio of 250 to 400 and a pressure of 50 to 70 mbar.

The second region formation step (S400) can be implemented with aluminum nitride (AlN) having excellent crystallinity.

Due to the large energy band gap (6.2 eV) of aluminum nitride (AlN), the flow of electrons, which are carriers of the conduction band, and holes, which are carriers of the valence band, is blocked.

Therefore, since it has electrical resistance, it has little heat generation and can maintain high resistance while being stable regardless of temperature changes.

In addition, the second region (320) having excellent crystallinity can implement excellent film formation quality of the channel region (420) grown thereon.

The present embodiment may further include a carbonization layer forming step (S150) for forming a carbonization layer (150) having a Si-C bond in which silicon (Si) and carbon (C) are bonded, between the growth substrate preparation step (100) and the nucleation region forming step (200), if the growth substrate is Si or SiC.

The carbonization layer forming step (S150) forms a carbonization layer (150) by carbonizing the surface of the growth substrate using a carbon dopant for carbon doping including C₂H₄ (ethylene) and propane (C₃H₈).

When the materials of the first region (310) and the second region (320) are aluminum nitride (AlN), aluminum gallium nitride (AlGaN), or gallium nitride (GaN), the group III (Al, Ga) or group V (N) elements that constitute them can act as dopants that cause damage (e.g., dangling bonds) to the surface of the SiC or Si growth substrate or diffuse into the inside.

The carbon layer forms a Si-C bonding layer on the surface of the growth substrate (100) in advance, thereby performing the role of an isolation layer that isolates the first region (310) and the second region (320) from the growth substrate (100).

Accordingly, the phenomenon in which the functions of the first region (310) and the second region (320) that can stably maintain high resistance characteristics are damaged during the manufacturing process can be prevented.

Therefore, the carbon layer makes it easier to manufacture GaN HEMTs with enhanced insulation.

What is claimed is:

1. An epitaxy wafer for a GaN HEMT with enhanced electrical insulation, comprising:
a growth substrate;
a nucleation region grown on the growth substrate;
a high-resistance region having electrically high resistance characteristics, which comprises a high-resistance unit region defined by a first region grown as a group III nitride semiconductor doped with carbon and a second region grown as a group III nitride semiconductor on the first region, which is provided on the nucleation region; and
an active region including a channel region grown on the high-resistance region and a barrier region grown on the channel region.

2. The epitaxy wafer of claim 1, wherein the high resistance region is provided by stacking the high resistance unit regions two or more times.

3. The epitaxy wafer of claim 1, wherein the first region is provided with a carbon doping concentration of 5×10¹⁷/cm³ or more.

4. The epitaxy wafer of claim 1, wherein the first region is formed of one of aluminum nitride (AlN), aluminum gallium nitride (AlGaN), or gallium nitride (GaN), and the second region is formed of aluminum nitride (AlN).

5. The epitaxy wafer of claim 1, further comprises a high-resistance GaN region made of aluminum gallium nitride (AlGaN) or gallium nitride (GaN) and provided between the high-resistance region and the active region.

6. A method for manufacturing an epitaxial wafer for a GaN HEMT with enhanced electrical insulation, comprising:
preparing a growth substrate;
forming a nucleation region by epitaxially growing a nucleation region on the growth substrate;
forming a first region by epitaxially growing a carbon-doped group III nitride semiconductor layer on the nucleation region;
forming a second region by epitaxially growing a group III nitride semiconductor layer at a temperature relatively higher than that of the first region forming step on the first region;
repeating the steps of forming the first and second regions; and
forming an active region by forming a channel region on the second region, the channel region having an energy bandgap smaller than that of the second region, and a barrier region grown on the channel region.

7. The method of claim 6, wherein the growth substrate is formed of silicon carbide (SiC) and silicon (Si) materials, the nucleation region is formed of aluminum nitride (AlN), the first region is formed of one of aluminum nitride (AlN), aluminum gallium nitride (AlGaN), and gallium nitride (GaN), and the second region is formed of aluminum nitride (AIN).

8. The method of claim 6, wherein the first region forming step is performed at a temperature of 900 to 1100° C., and the second region forming step is performed at a temperature of 1150 to 1300° C.

9. The method of claim 6, further comprises a step of forming a high-resistance GaN region made of aluminum gallium nitride (AlGaN) or gallium nitride (GaN) between the high-resistance region and the active region.

10. The method of claim 6, wherein the first region forming step is performed at a V/III Ratio of 250 to 400 and a pressure of 50 to 70 mbar.
